(19) United States
(12) Patent Application Publication
(10) Pub. No.: US 2011/0020616 A1
(43) Pub. Date: Jan. 27, 2011

(54) Method of Determining Overlay Error and a Device Manufacturing Method

(75) Inventors: Willem Marie Julia Marcel COENE, Geldrop (NL); Maurits Van Der Schaar, Eindhoven (NL)

Correspondence Address: STERNE, KESSLER, GOLDSTEIN & FOX P.L.L.C., 1100 NEW YORK AVENUE, N.W., WASHINGTON, DC, 20005, US

(73) Assignee: ASML Netherlands B.V., Veldhoven (NL)

(21) Appl. No.: 12/828,812

(22) Filed: Jul. 1, 2010

Related U.S. Application Data
(60) Provisional application No. 61/227,217, filed on Jul. 21, 2009.

(51) Int. Cl. G06F 19/00; G01N 21/47; G03F 7/20; B32B 3/10

(52) U.S. Cl. 428/195.1; 702/81; 430/322; 356/446

(57) ABSTRACT

A method of determining an overlay error in a set of superimposed patterns. The patterns are divided into two and a first part of the pattern has a bias of d+s/2 between the first layer and second layer. A second part of the pattern has a bias of d−s/2 between the first and second layer. The two parts of the pattern are of equal size. To eliminate a particular harmonic s is chosen to be T/(2n) where T is the period of the pattern and n is a positive integer.

### CROSS REFERENCE TO RELATED APPLICATIONS

This application claims benefit under 35 U.S.C. §119(e) to U.S. Provisional Application 61/227,217, filed Jul. 21, 2009, which is incorporated by reference herein in its entirety.

### BACKGROUND

1. Field of the Invention

The present invention relates to methods of inspection usable, for example, in the manufacture of devices by lithographic techniques and to methods of manufacturing devices using lithographic techniques.

2. Background Art

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the substrate parallel or anti-parallel to this direction. It is also possible to transfer the pattern from the patterning device to the substrate by imprinting the pattern onto the substrate.

In order to monitor the lithographic process, it is necessary to measure parameters of the patterned substrate, for example the overlay error between successive layers formed in or on it. There are various techniques for making measurements of the microscopic structures formed in lithographic processes, including the use of scanning electron microscopes and various specialized tools. One form of specialized inspection tool is a scatterometer in which a beam of radiation is directed onto a target on the surface of the substrate and properties of the scattered or reflected beam are measured. By comparing the properties of the beam before and after it has been reflected or scattered by the substrate, the properties of the substrate can be determined. This can be done, for example, by comparing the reflected beam with data stored in a library of known measurements associated with known substrate properties. Two main types of scatterometer are known. Spectroscopic scatterometers direct a broadband radiation beam onto the substrate and measure the spectrum (intensity as a function of wavelength) of the radiation scattered into a particular narrow angular range. Angularly resolved scatterometers use a monochromatic radiation beam and measure the intensity of the scattered radiation as a function of angle.

It is assumed that the diffraction pattern obtained with the large angle scatterometer comprises a plurality of non-overlapping or only partially overlapping diffraction orders and for the first and higher order diffraction orders, there is a pair of diffraction orders (±1^{st} order, ±2^{nd} order, ±3^{rd} order). Thus each pixel for first and higher orders of diffraction has an opposite pixel (making a pair of pixels) having an equal and opposite angle of diffraction. The asymmetry for a given angle of diffraction (or pair of pixels) is obtained by subtracting, from within the same diffraction order, the intensity of a pixel from the intensity of other pixel of pair (measured at the same point in time). The asymmetry of a detected beam can be modeled as a weighted sum of oscillating base functions and most commonly as a series of harmonics. Conventionally, when detecting the first diffraction orders from the measured diffraction pattern only the first order harmonic is used as higher order harmonics have decreasing significance. Two separate sets of superimposed patterns with opposite biases are used to determine the amplitude of the first order harmonic for each pixel in the detected diffraction pattern and the overlay error. However, ignoring the higher order harmonics can lead to intolerable offsets in the determined overlay error, if the second (or higher) order harmonic is sufficiently large and cannot be neglected.

The amplitude of the base function is known as the K value, and the K value for each pixel is determined resulting in a “K-map”. K values can be determined using a pair of superimposed patterns, and then the K-map can be reused on a target having only a single set of superimposed patterns. However, if the determined K-value is not accurate (for example due to neglecting higher order harmonics) then the overlay determined will also be inaccurate. Furthermore the K value may vary across the substrate due to process variation across the substrate, for example due to chemical mechanical polishing, and the K value may be determined at a location distant from the determined overlay error.

### SUMMARY

It is desirable to provide an improved method of modeling the asymmetry of diffraction orders.

According to an aspect of the invention, there is provided a method of measuring overlay error between a first population and a second population on a substrate, the second population being superimposed on the first population and the method comprising the following steps. Forming the first population on the substrate, the first population comprising a first pattern and a second pattern, the first pattern comprising a first area and a second area and having a repeating pattern with a period T₁, the second pattern comprising a third area and a fourth area and having a repeating pattern with a period T₁. Forming the second population on the substrate, the second population comprising a third pattern and a fourth pattern, the third pattern being superimposed over the first pattern and forming a first pattern stack, the third pattern having a fifth area and a sixth area and having a repeating pattern with a period T₁, the fifth area being nominally identical to the first area and superimposed over the first area and the sixth area being nominally identical to the second area and superimposed over the second area, the fourth pattern being superimposed over the second pattern and forming a second pattern stack, the fourth pattern having a seventh area and an eighth area and having a repeating pattern with a period T₁, the seventh area being nominally identical to the third area and superimposed over the third area and the eighth area being nominally identical to the fourth area and superimposed over the fourth area. Detecting a diffraction pattern from the first pattern stack. Detecting a diffraction pattern from the second pattern stack. Calculating the overlay error from the asymmetry of the diffraction patterns. The fifth area has a bias with respect to the first area of d₁−T₁/(4n), the sixth area has a bias with respect to the second area of d₁+T₁/(4n), the seventh area has a bias with respect to the third area of −d₁−T₁/(4n) and the eighth area has a bias with respect to the fourth area of −d₁+T₁/(4n) where n is a positive integer, the total area of the second area is equal to the area of the first area, the area of the fourth area is equal to the area of the third area, the area of the sixth area is equal to the area of the fifth area and the area of the eighth area is equal to the area of the seventh area.

A substrate comprising a first pattern stack and a second pattern stack, the first pattern stack having a first pattern and a third pattern, the third pattern being superimposed over the first pattern, the first pattern comprising a first area and a second area and having a repeating pattern with a period T₁, the third pattern comprising a fifth area and a sixth area and having a period T₁, the fifth area being nominally identical to the first area and superimposed over the first area and the sixth area being nominally identical to the second area and superimposed over the second area, the second pattern stack having a second pattern and a fourth pattern, the fourth pattern being superimposed over the second pattern, the second pattern comprising a third area and a fourth area and having a repeating pattern with a period T₁, the fourth pattern comprising a seventh area and a eighth area and having a period T₁, the seventh area being nominally identical to the third area and superimposed over the first area and the eighth area being nominally identical to the fourth area and superimposed over the fourth area wherein the fifth area has a bias with respect to the first area of d₁−T₁/(4n), the sixth area has a bias with respect to the second area of d₁+T₁/(4n), the seventh area has a bias with respect to the third area of −d₁−T₁/(4n) and the eighth area has a bias with respect to the fourth area of −d₁+T₁/(4n) where n is a positive integer and the total area of the second area is equal to the area of the first area, the area of the fourth area is equal to the area of the third area, the area of the sixth area is equal to the area of the fifth area and the area of the eighth area is equal to the area of the seventh area.

Further features and advantages of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the present invention and, together with the description, further serve to explain the principles of the invention and to enable a person skilled in the relevant art(s) to make and use the invention.

FIG. 1 depicts a lithographic apparatus.

FIG. 2 depicts a lithographic cell or cluster.

FIG. 3 depicts a first scatterometer.

FIG. 4 depicts a second scatterometer.

FIGS. 5A and 5B depict a patterns according to an embodiment of the invention.

FIG. 6 depicts an alternative pattern according to an embodiment of the invention.

FIG. 7 depicts an alternative pattern according to an embodiment of the invention.

FIG. 8 depicts an alternative pattern according to an embodiment of the invention.

FIG. 9 depicts an alternative pattern according to an embodiment of the invention.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements. The drawing in which an element first appears is indicated by the leftmost digit(s) in the corresponding reference number.

### DETAILED DESCRIPTION

### Overview

This specification discloses one or more embodiments that incorporate the features of this invention. The disclosed embodiment(s) merely exemplify the invention. The scope of the invention is not limited to the disclosed embodiment(s). The invention is defined by the claims appended hereto.

The embodiment(s) described, and references in the specification to “one embodiment”, “an embodiment”, “an example embodiment”, etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc.

Before describing such embodiments in more detail, however, it is instructive to present an example environment in which embodiments of the present invention may be implemented.

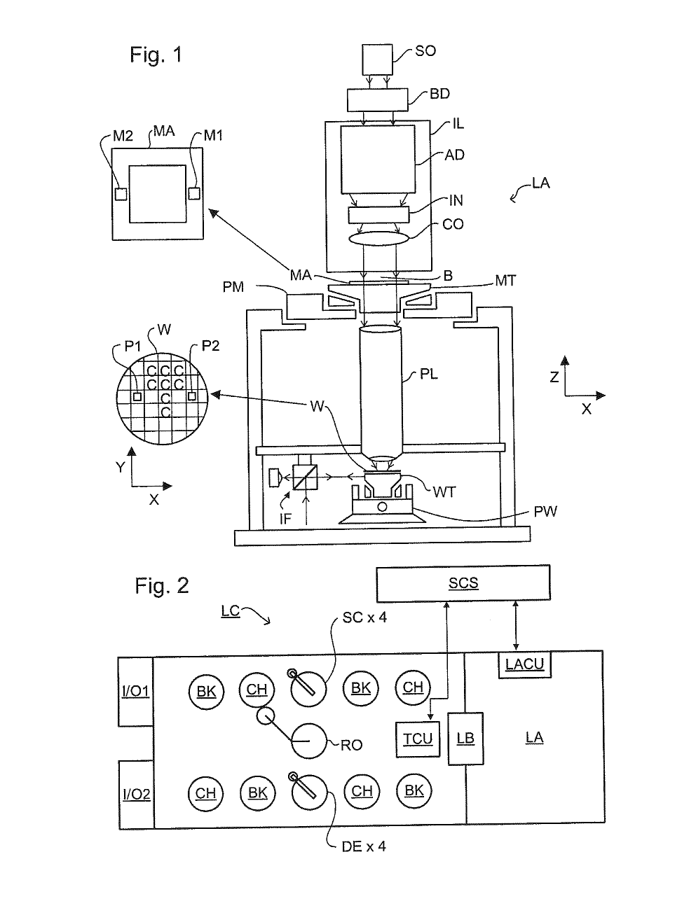

FIG. 1 schematically depicts a lithographic apparatus. The apparatus comprises an illumination system (illuminator) IL configured to condition a radiation beam B (e.g., UV radiation or DUV radiation), a support structure (e.g., a mask table) MT constructed to support a patterning device (e.g., a mask) MA and connected to a first positioner PM configured to accurately position the patterning device in accordance with certain parameters, a substrate table (e.g., a wafer table) WT constructed to hold a substrate (e.g., a resist-coated wafer) W and connected to a second positioner PW configured to accurately position the substrate in accordance with certain parameters, and a projection system (e.g., a refractive projection lens system) PL configured to project a pattern imparted to the radiation beam B by patterning device MA onto a target portion C (e.g., comprising one or more dies) of the substrate W.

The illumination system may include various types of optical components, such as refractive, reflective, magnetic, electromagnetic, electrostatic or other types of optical components, or any combination thereof, for directing, shaping, or controlling radiation.

The support structure supports, i.e., bears the weight of, the patterning device. It holds the patterning device in a manner that depends on the orientation of the patterning device, the design of the lithographic apparatus, and other conditions, such as for example whether or not the patterning device is held in a vacuum environment. The support structure can use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam, which is reflected by the mirror matrix.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

As here depicted, the apparatus is of a transmissive type (e.g., employing a transmissive mask). Alternatively, the apparatus may be of a reflective type (e.g., employing a programmable mirror array of a type as referred to above, or employing a reflective mask).

The lithographic apparatus may be of a type having two (dual stage) or more substrate tables (and/or two or more mask tables). In such “multiple stage” machines the additional tables may be used in parallel, or preparatory steps may be carried out on one or more tables while one or more other tables are being used for exposure.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

Referring to FIG. 1, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising, for example, suitable directing minors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may comprise an adjuster AD for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as an integrator IN and a condenser CO. The illuminator may be used to condition the radiation beam, to have a desired uniformity and intensity distribution in its cross-section.

The radiation beam B is incident on the patterning device (e.g., mask MA), which is held on the support structure (e.g., mask table MT), and is patterned by the patterning device. Having traversed the mask MA, the radiation beam B passes through the projection system PL, which focuses the beam onto a target portion C of the substrate W. With the aid of the second positioner PW and position sensor IF (e.g., an interferometric device, linear encoder, 2-D encoder or capacitive sensor), the substrate table WT can be moved accurately, e.g., so as to position different target portions C in the path of the radiation beam B. Similarly, the first positioner PM and another position sensor (which is not explicitly depicted in FIG. 1) can be used to accurately position the mask MA with respect to the path of the radiation beam B, e.g., after mechanical retrieval from a mask library, or during a scan. In general, movement of the mask table MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner) the mask table MT may be connected to a short-stroke actuator only, or may be fixed. Mask MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the mask MA, the mask alignment marks may be located between the dies.

The depicted apparatus could be used in at least one of the following modes:

1. In step mode, the mask table MT and the substrate table WT are kept essentially stationary, while an entire pattern imparted to the radiation beam is projected onto a target portion C at one time (i.e., a single static exposure). The substrate table WT is then shifted in the X and/or Y direction so that a different target portion C can be exposed. In step mode, the maximum size of the exposure field limits the size of the target portion C imaged in a single static exposure.

2. In scan mode, the mask table MT and the substrate table WT are scanned synchronously while a pattern imparted to the radiation beam is projected onto a target portion C (i.e., a single dynamic exposure). The velocity and direction of the substrate table WT relative to the mask table MT may be determined by the (de-)magnification and image reversal characteristics of the projection system PL. In scan mode, the maximum size of the exposure field limits the width (in the non-scanning direction) of the target portion in a single dynamic exposure, whereas the length of the scanning motion determines the height (in the scanning direction) of the target portion.

3. In another mode, the mask table MT is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

As shown in FIG. 2, the lithographic apparatus LA forms part of a lithographic cell LC, also sometimes referred to a lithocell or cluster, which also includes apparatus to perform pre- and post-exposure processes on a substrate. Conventionally these include spin coaters SC to deposit resist layers, developers DE to develop exposed resist, chill plates CH and bake plates BK. A substrate handler, or robot, RO picks up substrates from input/output ports I/O1, I/O2, moves them between the different process apparatus and delivers then to the loading bay LB of the lithographic apparatus. These devices, which are often collectively referred to as the track, are under the control of a track control unit TCU which is itself controlled by the supervisory control system SCS, which also controls the lithographic apparatus via lithography control unit LACU. Thus, the different apparatus can be operated to maximize throughput and processing efficiency.

In order that the substrates that are exposed by the lithographic apparatus are exposed correctly and consistently, it is desirable to inspect exposed substrates to measure properties such as overlay errors between subsequent layers, line thicknesses, critical dimensions (CD), etc. If errors are detected, adjustments may be made to exposures of subsequent substrates, especially if the inspection can be done soon and fast enough that other substrates of the same batch are still to be exposed. Also, already exposed substrates may be stripped and reworked—to improve yield—or discarded—thereby avoiding performing exposures on substrates that are known to be faulty. In a case where only some target portions of a substrate are faulty, further exposures can be performed only on those target portions which are good.

An inspection apparatus is used to determine the properties of the substrates, and in particular, how the properties of different substrates or different layers of the same substrate vary from layer to layer. The inspection apparatus may be integrated into the lithographic apparatus LA or the lithocell LC or may be a stand-alone device. To enable most rapid measurements, it is desirable that the inspection apparatus measure properties in the exposed resist layer immediately after the exposure. However, the latent image in the resist has a very low contrast—there is only a very small difference in refractive index between the parts of the resist which have been exposed to radiation and those which have not—and not all inspection apparatus have sufficient sensitivity to make useful measurements of the latent image. Therefore measurements may be taken after the post-exposure bake step (PEB) which is customarily the first step carried out on exposed substrates and increases the contrast between exposed and unexposed parts of the resist. At this stage, the image in the resist may be referred to as semi-latent. It is also possible to make measurements of the developed resist image—at which point either the exposed or unexposed parts of the resist have been removed—or after a pattern transfer step such as etching. The latter possibility limits the possibilities for rework of faulty substrates but may still provide useful information.

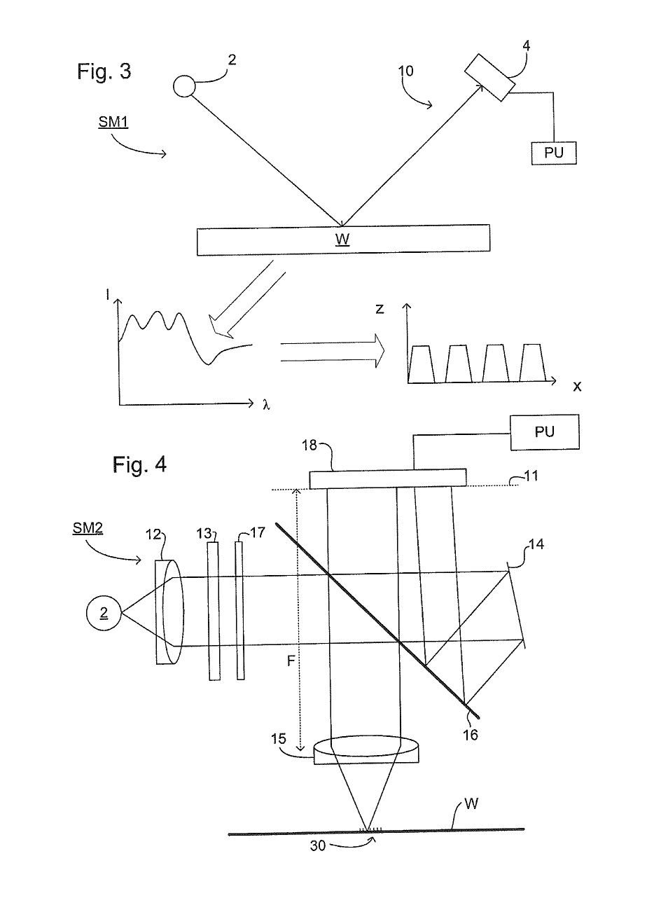

FIG. 3 depicts a scatterometer SM1 which may be used in the present invention. It comprises a broadband (white light) radiation projector 2 which projects radiation onto a substrate W. The reflected radiation is passed to a spectrometer detector 4, which measures a spectrum 10 (intensity as a function of wavelength) of the specular reflected radiation. From this data, the structure or profile giving rise to the detected spectrum may be reconstructed by processing unit PU, e.g., by Rigorous Coupled Wave Analysis and non-linear regression or by comparison with a library of simulated spectra as shown at the bottom of FIG. 3. In general, for the reconstruction the general form of the structure is known and some parameters are assumed from knowledge of the process by which the structure was made, leaving only a few parameters of the structure to be determined from the scatterometry data. Such a scatterometer may be configured as a normal-incidence scatterometer or an oblique-incidence scatterometer.

Another scatterometer SM2 that may be used with the present invention is shown in FIG. 4. In this device, the radiation emitted by radiation source 2 is focused using lens system 12 through interference filter 13 and polarizer 17, reflected by partially reflected surface 16 and is focused onto substrate W via a microscope objective lens 15, which has a high numerical aperture (NA), preferably at least 0.9 and more preferably at least 0.95. Immersion scatterometers may even have lenses with numerical apertures over 1. The reflected radiation then transmits through partially reflective surface 16 into a detector 18 in order to have the scatter spectrum detected. The detector may be located in the back-projected pupil plane 11, which is at the focal length of the lens system 15, however the pupil plane may instead be re-imaged with auxiliary optics (not shown) onto the detector. The pupil plane is the plane in which the radial position of radiation defines the angle of incidence and the angular position defines azimuth angle of the radiation. The detector is preferably a two-dimensional detector so that a two-dimensional angular scatter spectrum of a substrate target 30 can be measured. The detector 18 may be, for example, an array of CCD or CMOS sensors, and may use an integration time of, for example, 40 milliseconds per frame.

A reference beam is often used for example to measure the intensity of the incident radiation. To do this, when the radiation beam is incident on the beam splitter 16 part of it is transmitted through the beam splitter as a reference beam towards a reference mirror 14. The reference beam is then projected onto a different part of the same detector 18.

A set of interference filters 13 is available to select a wavelength of interest in the range of, say, 405-790 nm or even lower, such as 200-300 nm. The interference filter may be tunable rather than comprising a set of different filters. A grating could be used instead of interference filters.

The detector 18 may measure the intensity of scattered light at a single wavelength (or narrow wavelength range), the intensity separately at multiple wavelengths or integrated over a wavelength range. Furthermore, the detector may separately measure the intensity of transverse magnetic- and transverse electric-polarized light and/or the phase difference between the transverse magnetic- and transverse electric-polarized light.

Using a broadband light source (i.e., one with a wide range of light frequencies or wavelengths—and therefore of colors) is possible, which gives a large etendue, allowing the mixing of multiple wavelengths. The plurality of wavelengths in the broadband preferably each has a bandwidth of Δλ8 and a spacing of at least 2Δλ8 (i.e., twice the bandwidth). Several “sources” of radiation can be different portions of an extended radiation source which have been split using fiber bundles. In this way, angle resolved scatter spectra can be measured at multiple wavelengths in parallel. A 3-D spectrum (wavelength and two different angles) can be measured, which contains more information than a 2-D spectrum. This allows more information to be measured which increases metrology process robustness. This is described in more detail in EP1,628,164A, which is incorporated by reference herein in its entirety.

The target 30 on substrate W may be a grating, which is printed such that after development, the bars are formed of solid resist lines. The bars may alternatively be etched into the substrate. This pattern is sensitive to chromatic aberrations in the lithographic projection apparatus, particularly the projection system PL, and illumination symmetry and the presence of such aberrations will manifest themselves in a variation in the printed grating. Accordingly, the scatterometry data of the printed gratings is used to reconstruct the gratings. The parameters of the grating, such as line widths and shapes, may be input to the reconstruction process, performed by processing unit PU, from knowledge of the printing step and/or other scatterometry processes.

In order to determine the overlay error a plurality of sets of superimposed patterns are used. Each set of superimposed patterns has is given a known (and different) bias (in addition to the unknown overlay error). For each set of superimposed patterns (pattern stack) a diffraction pattern is detected, comprising at least first and possibly higher orders. The first or higher order diffraction pattern is used to detect an asymmetry, which is the intensity at a given angle subtracted from the intensity at an equal and opposite angle. An asymmetry can be calculated for each angle of reflection, or each pixel. The asymmetry is calculated and then modeled for each set of superimposed patterns, each set of superimposed patterns having a different bias. From the modeled asymmetry over a plurality of biases the overlay error can then be computed.

According to an embodiment of the invention, when the asymmetry can be modeled as a plurality of different oscillating base functions, each having a period T, of the pattern. The asymmetry is most commonly modeled as a series of harmonics. If higher order harmonics are considered, rather than simply the first harmonic, the detected asymmetry for each pixel, p, is:

$${A}_{p}^{\pm d} = {\sum }_{n = 0}^{∞} {K}_{n , p} sin [ n \frac{2 π}{T} x ]$$

where A is the asymmetry, x is the overlay plus the bias and K is the weight of each harmonic.

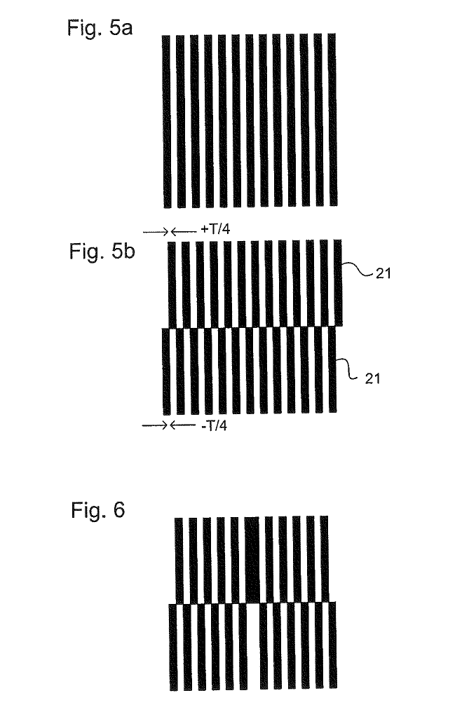

Each pattern is divided into two as shown in FIG. 5. FIG. 5a depicts the first population and FIG. 5b depicts the second population, superimposed on the first population and together forming a pattern stack. The upper portion of the pattern of the second population 21 has a bias of d+s/2 and the lower portion 22 of the pattern has a bias of d−s/2. The resultant asymmetry is:

$${A}_{p}^{\pm d} = {\sum }_{n = 0}^{∞} {K}_{n , p} sin [ n \frac{2 π}{T} ( x - s / 2 ) ] + {\sum }_{n = 0}^{∝} {K}_{n , p} sin [ n \frac{2 π}{T} ( x + s / 2 ) ]$$

s can be chosen to eliminate a particular harmonic. For example if s is chosen to be T/4, where T is the period of the pattern the second harmonic will be eliminated.

Although this has been described in conjunction with the second harmonic, any selected harmonic may be eliminated by suitably selecting s. To eliminate a particular (nth) harmonic the bias s should be selected to s=T/(2n) where n is a positive integer. The harmonics 3n, 5n, 7n, . . . will also simultaneously be eliminated. Preferably each of the pattern stacks used to determine the overlay error should be divided into two as described.

For an embodiment of the invention to work effectively, the radiation spot should be focused such that 50% of the beam is on the first portion of the pattern and 50% is on the second portion of the pattern.

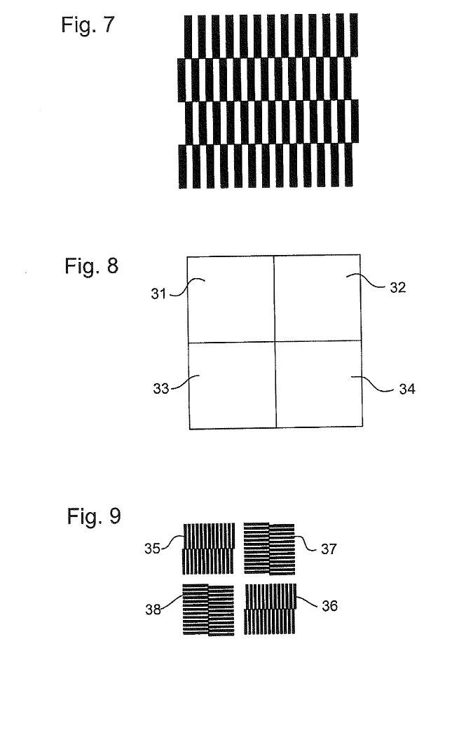

Although an embodiment of the invention has been depicted using a pattern divided into just two portions, it could be divided according to any scheme. For example, the pattern may be divided into four, as shown in FIG. 6, with two portions having a bias of s with respect to the other portions. Indeed any arrangement may be used, provided that the total area with a bias of d+s/2 is equal to the total area with a bias of d−s/2 and FIG. 7 depicts a pattern with four equal areas: two having a bias of d+T/8 and two having a bias of d−T/8. However, it has been found that a pattern divided along a line parallel to the period of the pattern results in fewer disturbing diffraction effects.

The embodiment depicted in FIGS. 5A and 5B showed the second (upper) pattern population being divided into with one portion being offset from the other portion. However, the first (lower) pattern population could equally be divided and have one portion offset from the other portion.

This invention can furthermore be used to suppress more than one harmonic. For example, if patterns are divided into four portions (rather than two) as depicted in FIG. 8. The first portion, 31, has a bias between the second population and the first population of d−T/(4n₁)−T/(4n₂), the second portion, 32, has a bias between the second population and the first population of d−T/(4n₁)+T/(4n₂), the third portion, 33, has a bias between the second population and the first population of d+T/(4n₁)−T/(4n₂) and the fourth portion, 34, has a bias between the second population and the first population of d+T/(4n₁)+T/(4n₂). The n₁th and n₂th. Thus if is chosen to be 2 and chosen to be 3 the second harmonic (in addition to the 6^{th}, 10^{th}, 14^{th}, . . . harmonics) and third harmonics (in addition to the 9^{th}, 15^{th}, 21^{st}, . . . harmonics) will be eliminated. Indeed even more harmonics may be eliminated by further subdividing the pattern into more portions: to eliminate another harmonic the pattern would be divided into 8 etc.

The substrate may comprise several pattern stacks 35, 36, 37, 38 as shown in FIG. 9 and each having a different bias d₁, d₂, d₃, dₙ. Thus the relative bias between the a first portion of the second population of the nth pattern and a first portion of the first population of the nth pattern dₙ−T₁/(4n) and the relative bias between the second portion of the second population of the nth pattern and the second portion of the first population of the nth pattern is dₙ+T₁/(4n). Furthermore some of the pattern stacks 35, 36, may be arranged with their repeating patterns arranged in a first direction and some 37, 38 may be arranged with their repeating patterns in a second direction, preferably perpendicularly to the first direction.

Although this description relates to sets of superimposed patterns on the substrate a grating is most commonly used.

This invention has been described in conjunction with the first order of the diffraction pattern, although it can be applicable to any higher order of the diffraction pattern.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

Although specific reference may have been made above to the use of embodiments of the invention in the context of optical lithography, it will be appreciated that the invention may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

The terms “radiation” and “beam” used herein encompass all types of electromagnetic radiation, including ultraviolet (UV) radiation (e.g., having a wavelength of or about 365, 355, 248, 193, 157 or 126 nm) and extreme ultra-violet (EUV) radiation (e.g., having a wavelength in the range of 5-20 nm), as well as particle beams, such as ion beams or electron beams.

The term “lens”, where the context allows, may refer to any one or combination of various types of optical components, including refractive, reflective, magnetic, electromagnetic and electrostatic optical components.

While specific embodiments of the invention have been described above, it will be appreciated that the invention may be practiced otherwise than as described. For example, the invention may take the form of a computer program containing one or more sequences of machine-readable instructions describing a method as disclosed above, or a data storage medium (e.g., semiconductor memory, magnetic or optical disk) having such a computer program stored therein.

It is to be appreciated that the Detailed Description section, and not the Summary and Abstract sections, is intended to be used to interpret the claims. The Summary and Abstract sections may set forth one or more but not all exemplary embodiments of the present invention as contemplated by the inventor(s), and thus, are not intended to limit the present invention and the appended claims in any way.

The present invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

The breadth and scope of the present invention should not be limited by any of the above-described exemplary embodiments, but should be defined only in accordance with the following claims and their equivalents.

What is claimed is:

1. A method comprising:
forming a first population on a substrate, the first population comprising a first pattern and a second pattern, the first pattern comprising a first area and a second area and having a repeating pattern with a period T1, the second pattern comprising a third area and a fourth area and having a repeating pattern with a period T1;
forming a second population on the substrate, the second population comprising a third pattern and a fourth pattern, the third pattern being superimposed over the first pattern and forming a first pattern stack, the third pattern having a fifth area and a sixth area and having a repeating pattern with a period T1, the fifth area being nominally identical to the first area and superimposed over the first area and the sixth area being nominally identical to the second area and superimposed over the second area, the fourth pattern being superimposed over the second pattern and forming a second pattern stack, the fourth pattern having a seventh area and an eighth area and having a repeating pattern with a period T1, the seventh area being nominally identical to the third area and superimposed over the third area and the eighth area being nominally identical to the fourth area and superimposed over the fourth area
detecting a diffraction pattern from the first pattern stack;
detecting a diffraction pattern from the second pattern stack;
calculating the overlay error from any asymmetry of the diffraction patterns,
wherein:
the fifth area has a bias with respect to the first area of d1−T1/(4n),
the sixth area has a bias with respect to the second area of d1+T1/(4n),
the seventh area has a bias with respect to the third area of −d1−T1/(4n), and
the eighth area has a bias with respect to the fourth area of −d1+T1/(4n),
wherein n is a positive integer,
wherein:
the total area of the second area is equal to the area of the first area,
the area of the fourth area is equal to the area of the third area,
the area of the sixth area is equal to the area of the fifth area, and
the area of the eighth area is equal to the area of the seventh area.

2. The method according to claim 1, wherein the first area comprises a plurality of segments and the fifth area comprises a plurality of segments.

3. The method according to claim 2, wherein the segments are non-continguous.

4. The method according to claim 1, wherein the second area comprises a plurality of segments and the sixth area comprises a plurality of segments.

5. The method according to claim 4, wherein the adjacent segments have a bias of d1−T1/(4n) alternating with segments having a bias of d1+T1/(4n).

6. The method according to claim 1, wherein n=2, the first area comprises a single area forming half the first pattern and the second area comprises a single area forming a different half the first pattern.

7. The method according to claim 1, wherein the first pattern and the second pattern each comprise a grating.

8. A method according to claim 1, wherein:
the first population comprises a fifth pattern and a sixth pattern,
the fifth pattern comprises a ninth area and a tenth area and having a repeating pattern with a period T2,
the sixth pattern comprises a eleventh area and a twelfth area and having a repeating pattern with a period T2,
the second population comprises a seventh pattern and an eighth pattern,
the seventh pattern being superimposed over the fifth pattern and forming a third pattern stack,
the seventh pattern having a thirteenth area and an fourteenth area and having a repeating pattern with a period T2,
the thirteenth area being nominally identical to the ninth area and superimposed over the ninth area and the fourteenth area being nominally identical to the tenth area and superimposed over the tenth area,
the eighth pattern being superimposed over the sixth pattern and forming a fourth pattern stack,
the eighth pattern having a fifteenth area and an sixteenth area and having a repeating pattern with a period T2,
the fifteenth area being nominally identical to the eleventh area and superimposed over the eleventh area and the sixteenth area being nominally identical to the twelfth area and superimposed over the twelfth area the method further comprising:
detecting a diffraction pattern from the third pattern stack;
detecting a diffraction pattern from the fourth pattern stack;
calculating the overlay error from the asymmetry of the diffraction pattern,
wherein:
the thirteenth area has a bias with respect to the ninth area of d2−T2/(4n),
the fourteenth area has a bias with respect to the tenth area of d2+T2/(4n),
the fifteenth area has a bias with respect to the eleventh area of −d2−T2/(4n), and
the sixteenth area has a bias with respect to the twelfth area of −d2+T2/(4n)
wherein n is a positive integer, and
wherein the total area of the tenth area is equal to the area of the ninth area, the area of the twelfth area is equal to the area of the eleventh area, the total area of the fourteenth area is equal to the area of the thirteenth area and the area of the sixteenth area is equal to the area of the fifteenth area.

9. The method according to claim 8, wherein T1=T2.

10. The method according to claim 9, wherein the repeating pattern of the third and fourth pattern stacks repeats in a direction perpendicular to the repeating direction of the repeating pattern of the first and second pattern stacks.

11. The method according to claim 1 wherein:
each of the areas is divided into 2 sub-areas of equal size,
the first sub-area of the fifth area being superimposed over the first sub-area of the first area and having a bias with respect to the first sub-area of the first area of d1−T1/(4n1)−T1/(4n2),
the second sub-area of the fifth area being superimposed over the second sub-area of the first area and having a bias with respect to the second sub-area of the first area of d1−T1/(4n1)+T1/(4n2),
the first sub-area of the sixth area being superimposed over the first sub-area of the second area and having a bias with respect to the first sub-area of the second area of d1+T1/(4n1)−T1/(4n2),
the second sub-area of the sixth area being superimposed over the second sub-area of the second area and having a bias with respect to the second sub-area of the second area of d1+T1/(4n1)+T1/(4n2),
the first sub-area of the seventh area being superimposed over the first sub-area of the third area and having a bias with respect to the first sub-area of the third area of −d1−T1/(4n1)−T1/(4n2),
the second sub-area of the seventh area being superimposed over the second sub-area of the third area and having a bias with respect to the second sub-area of the third area of −d1−T1/(4n1)+T1/(4n2),
the first sub-area of the eighth area being superimposed over the first sub-area of the fourth area and having a bias with respect to the first sub-area of the fourth area of −d1+T1/(4n1)−T1/(4n2),
the second sub-area of the eighth area being superimposed over the second sub-area of the fourth area and having a bias with respect to the second sub-area of the fourth area of −d1+T1/(4n1)+T1/(4n2),
wherein n1 and n2 area positive integers.

12. The method according to claim 11, wherein n1=2 and n2=3.

13. The method according to claim 1, wherein the first and second area from a checkerboard pattern.

14. The method according to claim 1 further comprising additional pattern stacks.

15. A device manufacturing method comprising:
using a lithographic apparatus to form a pattern on a substrate; and
determining an overlay error of the pattern by a method comprising:
forming a first population on a substrate, the first population comprising a first pattern and a second pattern, the first pattern comprising a first area and a second area and having a repeating pattern with a period T1, the second pattern comprising a third area and a fourth area and having a repeating pattern with a period T1;
forming a second population on the substrate, the second population comprising a third pattern and a fourth pattern, the third pattern being superimposed over the first pattern and forming a first pattern stack, the third pattern having a fifth area and a sixth area and having a repeating pattern with a period T1, the fifth area being nominally identical to the first area and superimposed over the first area and the sixth area being nominally identical to the second area and superimposed over the second area, the fourth pattern being superimposed over the second pattern and forming a second pattern stack, the fourth pattern having a seventh area and an eighth area and having a repeating pattern with a period T1, the seventh area being nominally identical to the third area and superimposed over the third area and the eighth area being nominally identical to the fourth area and superimposed over the fourth area
detecting a diffraction pattern from the first pattern stack;
detecting a diffraction pattern from the second pattern stack;
calculating the overlay error from any asymmetry of the diffraction patterns,
wherein:
the fifth area has a bias with respect to the first area of d1−T1/(4n),
the sixth area has a bias with respect to the second area of d1+T1/(4n),
the seventh area has a bias with respect to the third area of −d1−T1/(4n), and
the eighth area has a bias with respect to the fourth area of −d1+T1/(4n),
wherein n is a positive integer,
wherein:
the total area of the second area is equal to the area of the first area,
the area of the fourth area is equal to the area of the third area,
the area of the sixth area is equal to the area of the fifth area, and
the area of the eighth area is equal to the area of the seventh area

16. A substrate comprising:
a first pattern stack and a second pattern stack,
the first pattern stack having a first pattern and a third pattern,
the third pattern being superimposed over the first pattern,
the first pattern comprising a first area and a second area and having a repeating pattern with a period T1,
the third pattern comprising a fifth area and a sixth area and having a period T1,
the fifth area being nominally identical to the first area and superimposed over the first area and the sixth area being nominally identical to the second area and superimposed over the second area,
the second pattern stack having a second pattern and a fourth pattern,
the fourth pattern being superimposed over the second pattern,
the second pattern comprising a third area and a fourth area and having a repeating pattern with a period T1,
the fourth pattern comprising a seventh area and a eighth area and having a period T1,
the seventh area being nominally identical to the third area and superimposed over the first area and the eighth area being nominally identical to the fourth area and superimposed over the fourth area wherein the fifth area has a bias with respect to the first area of d1−T1/(4n),
the sixth area has a bias with respect to the second area of d1+T1/(4n),
the seventh area has a bias with respect to the third area of −d1−T1/(4n) and the eighth area has a bias with respect to the fourth area of −d1+T1/(4n)
wherein n is a positive integer,
the total area of the second area is equal to the area of the first area,
the area of the fourth area is equal to the area of the third area,
the area of the sixth area is equal to the area of the fifth area, and
the area of the eighth area is equal to the area of the seventh area.
